(19) United States
(12) Patent Application Publication
(10) Pub. No.: US 2025/0067598 A1
(43) Pub. Date: Feb. 27, 2025

(54) METHOD OF MANUFACTURING A SPECTROMETER DEVICE

(71) Applicant: TRINAMIX GMBH, Ludwigshafen Am Rhein (DE)

(72) Inventor: Moritz LAUBSCHER, Ludwigshafen am Rhein (DE)

(21) Appl. No.: 18/841,867

(22) PCT Filed: Mar. 27, 2023
(86) PCT No.: PCT/EP23/57800

§ 371 Date: Aug. 27, 2024

(30) Foreign Application Priority Data
Mar. 28, 2022 (EP) 22164666.4

(51) Int. Cl. G01J 3/28; H01L 27/146

(52) U.S. Cl. CPC G01J 3/2803; H01L 27/14618; H01L 27/14634; H01L 27/14636; H01L 27/1469; H01L 27/14698

(57) ABSTRACT

Described herein is a method of manufacturing at least one spectrometer device for evaluating electromagnetic radiation. The method includes: a) providing at least one electro-optical system configured for generating at least one electronic signal according to the electromagnetic radiation; b) providing at least one readout integrated circuit (ROIC) for processing the at least one electronic signal; c) providing at least one circuit carrier; d) arranging the electro-optical system on the ROIC; e) bonding the electro-optical system and the ROIC to establish at least one electrical connection between the electro-optical system and the ROIC; and f) arranging the ROIC on the circuit carrier, such that the ROIC is located between the electro-optical system and the circuit carrier. Also described herein is a spectrometer device for evaluating electromagnetic radiation.

### TECHNICAL FIELD

The invention relates to a method of manufacturing at least one spectrometer device for evaluating electromagnetic radiation. Furthermore, the invention relates to a spectrometer device for evaluating electromagnetic radiation. Spectrometer devices can, in general, be employed in various areas for sensing, monitoring and detecting purposes, such as, for example, in medical and physiological diagnostics and research as well as in quality control and in various other fields. However, further kinds of applications are feasible.

### BACKGROUND ART

Various spectrometer devices and methods of manufacturing such for evaluating electromagnetic radiation are known. Thus, in general, spectrometer devices are known to collect information on the composition of electromagnetic radiation from an object, when irradiating, reflecting and/or absorbing electromagnetic radiation. Depending on the intended application, the size and complexity of the spectrometer devices vary. For the integration of spectrometer devices into known devices, such as into consumer devices, household devices, handheld devices or the like, the spectrometer devices have to be very compact. Specifically, substrate or lateral space, such as the available installation space for spectrometer devices on a circuit board of consumer devices, is limited.

Furthermore, stray light or diffracted light leads to faulty and distorted measurements. These phenomena become even more and more sensitive with the trends to smaller footprints and more densely packed systems.

### Problem to be Solved

It is therefore desirable to provide methods and devices that at least substantially avoid the disadvantages of known methods and devices. In particular, it is an object of the present invention to provide methods and devices aiming for a compact but still reliable spectrometer device.

### SUMMARY

This problem is addressed by a method of manufacturing at least one spectrometer device for evaluating electromagnetic radiation and by a spectrometer device for evaluating electromagnetic radiation with the features of the independent claims. Advantageous embodiments which might be realized in an isolated fashion or in any arbitrary combinations are listed in the dependent claims as well as throughout the specification.

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, non-withstanding the fact that the respective feature or element may be present once or more than once.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such way with other optional or non-optional features of the invention.

In a first aspect, the present invention relates to a method of manufacturing at least one spectrometer device for evaluating electromagnetic radiation. The method may also be referred to as “manufacturing method”. The method comprises the following method steps that may be performed in the given order. However, different order may also be possible. Further, one, more than one or even all of the method steps may be performed once or repeatedly. Furthermore, the method steps may be performed successively or, alternatively, two or more method steps may be performed in a timely overlapping fashion or even in parallel. The method may further comprise additional method steps that are not listed.

The method comprises the following steps:
a) providing at least one electro-optical system configured for generating at least one electronic signal according to the electromagnetic radiation;
b) providing at least one readout integrated circuit (ROIC) for processing the at least one electronic signal;
c) providing at least one circuit carrier;
d) arranging the electro-optical system on the ROIC;
e) bonding the electro-optical system and the ROIC such as to establish at least one electrical connection between the electro-optical system and the ROIC;
f) arranging the ROIC on the circuit carrier, such that the ROIC is located between the electro-optical system and the circuit carrier.

The term “spectrometer device” as used herein is a broad term and is to be given its ordinary and customary meaning to a person of ordinary skill in the art and is not to be limited to a special or customized meaning. The term specifically may refer, without limitation, to a device for acquiring at least one item of spectral information on at least one object by using electromagnetic radiation. Specifically, the at least one item of spectral information may refer to at least one optical property or optically measurable property that is determined as a function of a wavelength, for one or more different wavelengths of the electromagnetic radiation. More specifically, the at least one item of spectral information may relate to at least one property characterizing at least one of a transmission, an absorption, a reflection and an emission of the at least one object. The at least one optical property, may be determined for one or more wavelengths of the electromagnetic radiation. The spectrometer device specifically may relate to an apparatus that is capable of recording and processing a signal intensity of electromagnetic radiation with respect to a corresponding wavelength of a spectrum or a partition thereof, such as a wavelength interval, wherein the signal intensity is provided by the electro-optical system as an electronic signal which is then processed by the ROIC.

The term “electro-optical system” as used herein is a broad term and is to be given its ordinary and customary meaning to a person of ordinary skill in the art and is not to be limited to a special or customized meaning. The term specifically may refer, without limitation, to an optical sensor configured for generating an electronic signal according to the electromagnetic radiation, specifically according to its exposure to the electromagnetic radiation. As an example, the electro-optical system may comprise an array of individual pixel sensors, wherein each of the individual pixel sensors has at least a photosensitive area, which is adapted for generating an electronic and/or electrical signal depending on an illumination of the photosensitive area by at least a portion of the electromagnetic radiation, e.g. depending on the intensity of the electromagnetic radiation. Herein, the photosensitive area as comprised by each of the individual pixel sensors may be a single, uniform photosensitive area that is configured for receiving the electromagnetic radiation, which impinges on the individual pixel sensor. As an example, the photosensitive area may be or may comprise at least one photoconductor, in particular an inorganic photoconductor, especially PbS, PbSe, Ge, InGaAs, ext. InGaAs, InSb, or HgCdTe. Other photosensitive areas may be possible. The electro-optical system may specifically be designed to generate electrical or electronic signals associated with the intensity of the electromagnetic radiation that impinges on the individual pixel sensors. For example, the electro-optical system may comprise one or more filters and/or analogue-digital-converters, i.e. for converting optical into electronic signals. The electronic signals for adjacent individual pixel sensors may accordingly be generated simultaneously or else in a temporally successive manner. By way of example, during a row scan or line scan, it is possible to generate a sequence of electronic signals, which correspond to the series of the individual pixel sensors that are arranged in a line or a matrix.

The term “readout integrated circuit”, usually abbreviated to “ROIC”, as used herein is a broad term and is to be given its ordinary and customary meaning to person of ordinary skill in the art and is not to be limited to a special or customized meaning. The term specifically may refer, without limitation, to a signal processing device comprising at least one integrated circuit and configured for processing the at least one electronic signal generated by the electro-optical system. For example, the ROIC may be configured for transmitting these processed electronic signals, for example via a printed circuit board, to an evaluation unit configured for determining at least one item of spectral information according to the electromagnetic radiation. In particular, the ROIC may be configured for accumulating electronic signals for individual pixel sensors of the electro-optical system. Additionally or alternatively, the ROIC may be adapted to one or more of storing and amplifying the electronic signals, i.e. while maintaining signal-to-noise ratio. For this purpose, the ROIC may for example comprise one or more filters and/or other components for processing the electronic signals. In particular, the ROIC may be or may comprise one or more application-specific integrated circuits (ASICs) and/or one or more data processing devices.

The term “circuit carrier” as used herein is a broad term and is to be given its ordinary and customary meaning to person of ordinary skill in the art and is not to be limited to a special or customized meaning. The term specifically may refer, without limitation, to an element comprising a substrate, specifically a planar, electrically non-conductive substrate material, configured for mechanically supporting electrical modules, such as dies, specifically integrated circuit dies. The substrate may comprise a glass epoxy. However, other non-conductive materials may also be used as substrate material. The circuit carrier, besides the non-conductive, i.e. electrically insulating, substrate material, may further comprise layers and/or lines of conductive materials. As an example, the circuit carrier may be or may comprise a supporting case, e.g. configured for preventing damage and erosion of printed circuit board, usually abbreviated to “PCB”, which refers to an electrically non-conductive, planar substrate, also denoted as “board”, on which at least one sheet of an electrically conductive material, in particular a copper layer, is applied, specifically laminated, to the substrate, and which, in addition, comprises one or more electronic, electrical, and/or optical elements. Other terms which refer to this type of circuit carrier are printed circuit assembly, short “PCA”, printed circuit board assembly, short “PCB assembly” or “PCBA”, circuit card assembly, short “CCA”, or simply “card”. Other forms and/or arrangements of circuit carriers may be possible.

In particular, step f) of the method comprises arranging the ROIC, specifically the ROIC having the electro-optical system bonded thereto, on the circuit carrier, such that the ROIC is located between the electro-optical system and the circuit carrier. Thus, as an example, the electro-optical system may be arranged on a side of the ROIC facing away from the circuit carrier, such that the electro-optical system and the ROIC form a stack, such as a chip stack, that is arranged on the circuit carrier. Herein, the stack of electro-optical system and ROIC may also be referred to as spectrometer on chip stack, for example abbreviated to “SoC-stack”.

In step b), as an example, the at least one ROIC may be provided as a ROIC wafer. The term “ROIC wafer” as used herein is a broad term and is to be given its ordinary and customary meaning to a person of ordinary skill in the art and is not to be limited to a special or customized meaning. The term specifically may refer, without limitation, to a slice comprising a semiconductor, such as a crystalline silicon (c-Si), forming multiple ROICs. Specifically the ROIC wafer may be or may comprise a disc of semiconductor material, i.e. a slice of a monocrystalline silicon ingot, which has been treated and/or processed, i.e. by deposition, removal, patterning and/or modification of electrical properties, to comprise and/or form multiple ROICs.

Specifically, in case the ROIC is provided as a ROIC wafer in step b), the method may further comprise step g) of singulating the ROIC from the ROIC wafer. The term “singulating” as used herein is a broad term and is to be given its ordinary and customary meaning to a person of ordinary skill in the art and is not to be limited to a special or customized meaning. The term specifically may refer, without limitation, to a process of dicing and/or separating by one or more of scribing, breaking, sawing, for example mechanical sawing by using a dicing saw, and laser cutting. The singulating and/or dicing may be an automated process. In particular, the ROIC wafer may be singulated into individual ROICs, such as into individual ROIC dies, for example into individual bare semiconductor chip elements.

Step g) may be performed after performing step d). Thus, as an example, when manufacturing a spectrometer device, i.e. when performing the manufacturing method, the at least one electro-optical system may be arranged on the ROIC wafer, specifically, one electro-optical system may be arranged on each of the ROIC from the wafer. In particular, the electro-optical system may be arranged on the ROIC while the ROIC is still part of the wafer, i.e. of the ROIC wafer, such as on wafer-level.

Step g) may be performed after performing step d) and before performing step e). In particular, the singulating, i.e. step g), may be performed between steps d) and e). Thus, the electro-optical system may be arranged on the ROIC while the ROIC is still part of the wafer, but may be singulated before bonding the electro-optical system to the ROIC.

Step g) may be performed after performing step e). In particular, the singulating, i.e. step g), may be performed after step e). Thus, the electro-optical system may be arranged on and bonded to the ROIC while the ROIC is still part of the wafer. For example, wafer-level bonding of the electro-optical system onto the ROIC may be performed, such that the electrical connection between the electro-optical system and the ROIC is established while the ROIC is still part of the wafer, i.e. the ROIC wafer.

In step b), as an example, the at least one ROIC may be provided as a singulated ROIC, i.e. as an individual bare semiconductor chip element. Thus, alternatively to providing the ROIC wafer, in step b), the at least one ROIC may be provided as a previously singulated ROIC. In particular, at least steps d) and e) may be performed by using a singulated ROIC. Thus, as an example, the electro-optical system may be arranged on and bonded to a singulated ROIC.

As an example, in step e) the bonding may comprise performing one or more of the processes selected from the group consisting of: a wire bonding process, a flip chip bonding process and a tape-automated boding process. In particular, at least one of these processes may be used for bonding, i.e. electrically interconnecting, the electro-optical system and the ROIC.

Step d) further comprises gluing the electro-optical system to the ROIC by applying at least one adhesive material. As an example, the gluing may be performed before performing the bonding process in step e). Specifically, step d) may further comprise gluing the electro-optical system to the ROIC, before performing e.g. the wire bonding process in step e), by using at least one electrically insulating adhesive material. As an example, in step d), the electro-optical system is glued to the ROIC by applying the at least one adhesive material, wherein the adhesive material may for example be a non-conductive adhesive or glue, e.g. for mechanically stabilizing the arrangement. For this purpose, in step d), a non-conductive glue or adhesive may be used. In detail, in step d), the adhesive material is selected from the group consisting of: a thermosetting material, specifically an epoxy resin; a thermoplastic material; a plastic material; a polymer material; a silicone-based glue.

In particular, when arranging the electro-optical system on the ROIC wafer, i.e. when performing step d) before singulating the ROIC from the ROIC wafer, the electro-optical system may be glued onto the ROIC. Thus, the electro-optical system may be glued onto the ROIC while the ROIC is still part of the ROIC wafer, e.g. wafer-level gluing of the electro-optical system onto the ROIC may be performed.

Step f) may further comprise gluing the ROIC with the electro-optical system, such as the spectrometer on chip stack, i.e. the SoC-stack, to the circuit carrier, for example by using an adhesive material as outlined above with regard to an optional gluing in step d). Thus, as an example, when arranging the ROIC on the circuit carrier in step f), i.e. when arranging the spectrometer on chip stack, i.e. the SoC-stack, on the circuit carrier, an adhesive material may be used for mechanically stabilizing the arrangement.

Additionally or alternatively, step f) may comprise bonding the ROIC, specifically the ROIC with the electro-optical system, such as the spectrometer on chip stack, i.e. the SoC-stack, to the circuit carrier such as to establish at least one electrical connection between the ROIC and the circuit carrier, for example by a flip chip bonding process. However, other bonding processes, such as one or more of a wire bonding process and a tape-automated bonding process may also be possible.

Additionally or alternatively, step f) may comprise packaging the ROIC with the electro-optical system, i.e. at least partially encapsulating the joint ROIC and electro-optical system, thereby generating a packaged chip, such as a packaged spectrometer on chip stack, i.e. a packaged SoC-stack. Further, step f) may comprise placing and bonding the packaged chip on the circuit carrier, such as to establish at least one electrical connection between the packaged chip and the circuit carrier. Thus, as an example, step f) may comprise packaging the ROIC with the electro-optical system, i.e. generating a packaged SoC-stack, and then placing and bonding the packaged SoC-stack on the circuit carrier, such as to establish at least one electrical connection between the packaged SoC and the circuit carrier.

Further, the method may comprise the following step:
h) providing at least one housing and gluing the ROIC, specifically including the thereon arranged electro-optical system, to the housing by applying at least one further adhesive material.

The further adhesive material may be selected from the group consisting of: a thermosetting material, specifically an epoxy resin; a thermoplastic material; a plastic material; a polymer material; a silicone-based glue. In particular, the further adhesive optionally configured for gluing the ROIC to the housing may be selected from that group. Specifically, the further adhesive which may be used for gluing the ROIC with the electro-optical system arranged thereon, may be selected from that group. As an example, the further adhesive material may be the same adhesive material applied for gluing the electro-optical system to the ROIC in step d). However, alternatively, the adhesive material applied in step d) may differ from the further adhesive material.

In particular, the housing may be configured for providing stabilizing means for the spectrometer device and may be or may comprise at least one housing material, such as one or more of a plastic and/or metal material.

In a further aspect of the present invention, a spectrometer device for evaluating electromagnetic radiation is disclosed. The spectrometer device comprises at least one circuit carrier, at least one electro-optical system configured for generating at least one electronic signal according to the electromagnetic radiation; and at least one readout integrated circuit (ROIC) for processing the at least one electronic signal, wherein the ROIC is arranged between the circuit carrier and the electro-optical system. In particular, the electro-optical system is glued to the ROIC by at least one adhesive material selected from the group consisting of: a thermosetting material; a thermoplastic material; a plastic material; a polymer material; a silicone-based glue.

The spectrometer device may specifically be manufactured at least partially by performing the method of manufacturing a spectrometer device as described elsewhere in this document, i.e. as outlined above or as described in further detail below, is disclosed. Accordingly, the spectrometer device. Thus, specifically with regard to the definition of terms reference may be made to the description of the method of manufacturing at least one spectrometer device, specifically of the manufacturing method. In particular, the spectrometer device may be obtainable by performing the manufacturing method as described herein.

The electro-optical system may specifically be or may comprise an array of individual pixel sensors, such as a detector array. As an example, each of the individual pixel sensors may have at least one photosensitive area adapted for generating the at least one electronic signal depending on an illumination of the photosensitive area by at least a portion of the electromagnetic radiation. Thus, the electro-optical system may be or may comprise an array of pixel sensors and may generate multiple electronic signals, such as by generating at least one electronic signal by one or more of the pixel sensors.

The ROIC may be or may comprise at least one bare semiconductor chip element previously separated from a wafer.

The electro-optical system may be bonded, specifically electrically connected, to the ROIC by at least one interconnecting element. As an example, the electro-optical system may be electrically connected to the ROIC by the at least one interconnecting element. Thus, the at least one interconnecting element, may further be comprised by the spectrometer device. In particular, the interconnecting element may be or may comprise a wire and/or a solder bump. As an example, the interconnecting element, specifically the interconnecting element electrically connecting the ROIC and the electro-optical system, may be generated and/or established by one or more of a wire bonding process, a flip chip bonding process and a tape-automated boding process.

Further, the spectrometer device may comprise at least one wavelength-selective element configured for separating the electromagnetic radiation into a spectrum of constituent wavelength signals, wherein the wavelength-selective element is arranged in an optical path between a source of the electromagnetic radiation, specifically an external source, and the electro optical system.

The described methods and devices have considerable advantages over the prior art. Thus, in particular, the present methods and devices may allow for reducing the risk of erroneous measurements by increasing accuracy and precision of spectroscopic measurements. In particular, the present methods and devices may increase measurement precision by avoiding stray light, e.g. stray light reflected by or transmitted through the substrate, e.g. the circuit carrier.

Further, the spectrometer device as proposed herein may be smaller and more compact than known devices while at the same time showing a simpler and less complex built. In particular, the present methods and devices may specifically allow for an integration of spectroscopy functions into portable devices, such as into widespread consumer applications. In particular, the spectrometer devices as described herein, for example due to its compact, may be integrated into portable devices, thereby increasing the field of application of spectroscopy, such as by allowing for transferring applications from analytical labs to a widespread consumer application.

Further, the methods and devices proposed herein, specifically by gluing, for example compared to welding and/or other fastening and/or fixing means, may allow for a less complex, less expensive and thus simpler manufacturing of spectrometer devices, since the components may not have to be configured to be temperature stable. In particular, the proposed methods and devices, for example due to being glued, may not be subjected to high temperature fluctuations.

Summarizing, in the context of the present invention, and without excluding further possible embodiments, the following embodiments may be envisaged:

Embodiment 1: A method of manufacturing at least one spectrometer device for evaluating electromagnetic radiation, the method comprising:
a) providing at least one electro-optical system configured for generating at least one electronic signal according to the electromagnetic radiation;
b) providing at least one readout integrated circuit (ROIC) for processing the at least one electronic signal;
c) providing at least one circuit carrier;
d) arranging the electro-optical system on the ROIC;
e) bonding the electro-optical system and the ROIC such as to establish at least one electrical connection between the electro-optical system and the ROIC;
f) arranging the ROIC on the circuit carrier, such that the ROIC is located between the electro-optical system and the circuit carrier.

Embodiment 2: The method according to the preceding embodiment, wherein in step b) the at least one ROIC is provided as a ROIC wafer, wherein the method further comprises:
g) singulating the ROIC from the ROIC wafer.

Embodiment 3: The method according to the preceding embodiment, wherein step g) is performed after performing step d), specifically after performing step e).

Embodiment 4: The method according to embodiment 1, wherein in step b) the at least one ROIC is provided as singulated ROIC.

Embodiment 5: The method according to anyone of the preceding embodiments, wherein in step e) the bonding comprises performing one or more of the processes selected from the group consisting of: a wire bonding process, a flip chip bonding process and a tape-automated boding process.

Embodiment 6: The method according to any one of the preceding embodiments, wherein step d) further comprises gluing the electro-optical system to the ROIC by applying at least one adhesive material, specifically at least one electrically insulating adhesive material.

Embodiment 7: The method according to the preceding embodiment, wherein the adhesive material is selected from the group consisting of: a thermosetting material, specifically an epoxy resin; a thermoplastic material; a plastic material; a polymer material; a silicone-based glue.

Embodiment 8: The method according to any one of the preceding embodiments, wherein step f) comprises bonding the ROIC to the circuit carrier such as to establish at least one electrical connection between the ROIC and the circuit carrier, for example by a flip chip bonding process.

Embodiment 9: The method according to any one of the preceding embodiments, wherein step f) comprises packaging the ROIC with the electro-optical system thereby generating a packaged chip and then placing and bonding the packaged chip on the circuit carrier, such as to establish at least one electrical connection between the packaged chip and the circuit carrier.

Embodiment 10: The method according to any one of the preceding embodiments, wherein the method further comprises:
h) providing at least one housing and gluing the ROIC, specifically including the thereon arranged electro-optical system, to the housing by applying at least one further adhesive material.

Embodiment 11: The method according to the preceding embodiment, wherein the further adhesive material is selected from the group consisting of: a thermosetting material, specifically an epoxy resin; a thermoplastic material; a plastic material; a polymer material; a silicone-based glue.

Embodiment 12: A spectrometer device for evaluating electromagnetic radiation, the spectrometer device comprising:
a. at least one circuit carrier;
b. at least one electro-optical system configured for generating at least one electronic signal according to the electromagnetic radiation; and
c. at least one readout integrated circuit (ROIC) for processing the at least one electronic signal, wherein the ROIC is arranged between the circuit carrier and the electro-optical system.

Embodiment 13: The spectrometer device according to the preceding embodiment, wherein the electro-optical system is glued to the ROIC by at least one adhesive material selected from the group consisting of: a thermosetting material; a thermoplastic material; a plastic material; a polymer material; a silicone-based glue.

Embodiment 14: The spectrometer device according to any one of the preceding embodiments referring to a spectrometer device, wherein the spectrometer device is manufactured at least partially by performing the method of manufacturing a spectrometer device according to any one of the preceding method embodiments.

Embodiment 15: The spectrometer device according to any one of the preceding embodiments referring to a spectrometer device, wherein the electro-optical system comprises an array of individual pixel sensors, wherein each of the individual pixel sensors has at least one photosensitive area adapted for generating the at least one electronic signal depending on an illumination of the photosensitive area by at least a portion of the electromagnetic radiation.

Embodiment 16: The spectrometer device according to any one of the preceding embodiments referring to a spectrometer device, wherein the ROIC comprises at least one bare semiconductor chip element previously separated from a wafer.

Embodiment 17: The spectrometer device according to any one of the preceding embodiments referring to a spectrometer device, wherein the electro-optical system is bonded, specifically electrically connected, to the ROIC by at least one interconnecting element, such as by a wire and/or a solder bump, specifically established by one or more of a wire bonding process, a flip chip bonding process and a tape-automated boding process.

Embodiment 18: The spectrometer device according to any one of the preceding embodiments referring to a spectrometer device, further comprising at least one wavelength-selective element configured for separating the electromagnetic radiation into a spectrum of constituent wavelength signals, wherein the wavelength-selective element is arranged in an optical path between a source of the electromagnetic radiation, specifically an external source, and the electro optical system.

### SHORT DESCRIPTION OF THE FIGURES

Further optional features and embodiments will be disclosed in more detail in the subsequent description of embodiments, preferably in conjunction with the dependent claims. Therein, the respective optional features may be realized in an isolated fashion as well as in any arbitrary feasible combination, as the skilled person will realize. The scope of the invention is not restricted by the preferred embodiments. The embodiments are schematically depicted in the Figures. Therein, identical reference numbers in these Figures refer to identical or functionally comparable elements.

In the Figures:

FIGS. 1a, 1b and 1c show different embodiments of a spectrometer device in cross section views;

FIGS. 2a and 2b show different flow charts of a method of manufacturing at least one spectrometer device; and

FIGS. 3 to 6 show different schematic illustrations of a method of manufacturing at least one spectrometer device.

### DETAILED DESCRIPTION OF THE EMBODIMENTS

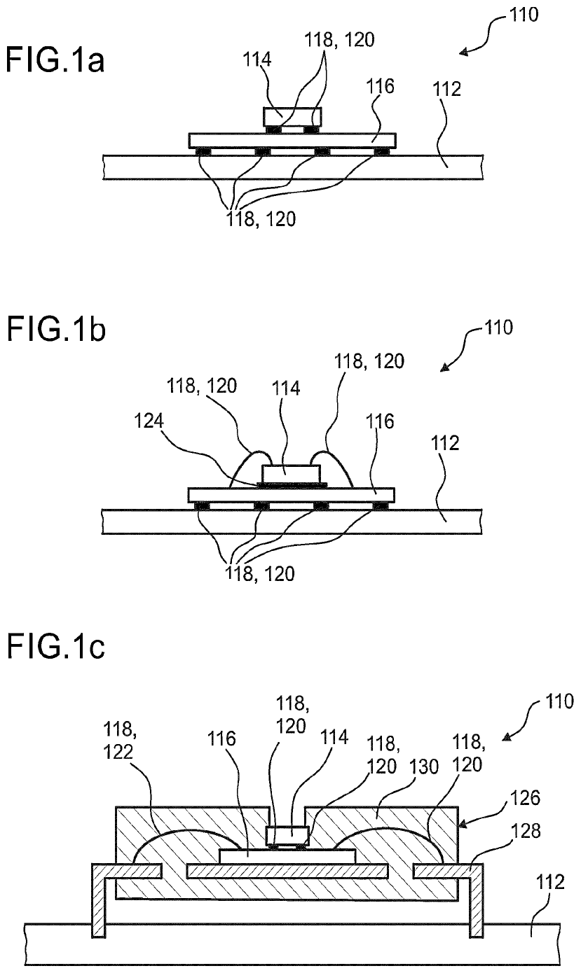

In FIGS. 1a, 1b and 1c, different embodiments of a spectrometer device 110 for evaluating electromagnetic radiation is illustrated. The spectrometer device 110 comprises a circuit carrier 112, an electro-optical system 114 configured for generating at least one electronic signal according to the electromagnetic radiation, and a readout integrated circuit (ROIC) 116 for processing the at least one electronic signal. The ROIC 116 is arranged between the circuit carrier 112 and the electro-optical system 114. In particular, the electro-optical system 114 may be arranged on a side of the ROIC 116 facing away from the circuit carrier 112. Further, the electro-optical system 114 may be bonded to the ROIC 116 by one or more interconnecting elements 118. Such an interconnecting element 118 may for example be a solder bump 120 and/or a wire 122, such as an interconnecting wire. Further, the electro-optical system 114 may be glued onto the ROIC 116 by using an adhesive material 124, specifically additionally to the one or more interconnecting elements 118.

Further, additional interconnecting elements 118 may be used for electrically connecting the ROIC 116 and the circuit carrier 112. As an example, the ROIC 116 and the circuit carrier 112 may be connected by solder bumps 120, e.g. the connection generated in a flip chip bonding process. However, other forms of electrically connecting the ROIC 116 and the circuit carrier 112 may be possible. As an example, the ROIC 116 and the electro-optical system 114 may be combined in a packaged chip 126, e.g. comprising a lead frame 128, one or more interconnecting wires 122 and a housing 130, wherein the packaged chip 126 may be arranged on the circuit carrier 112.

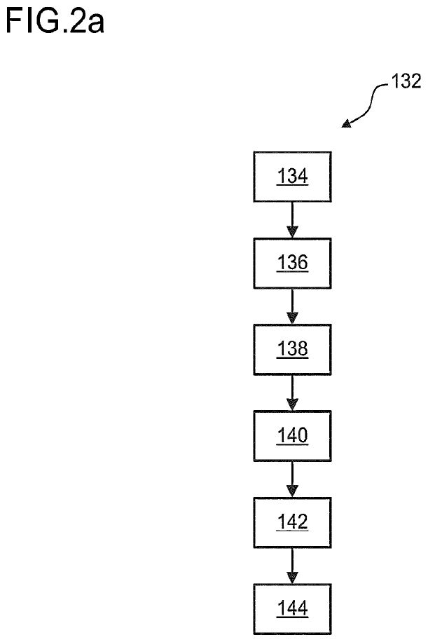

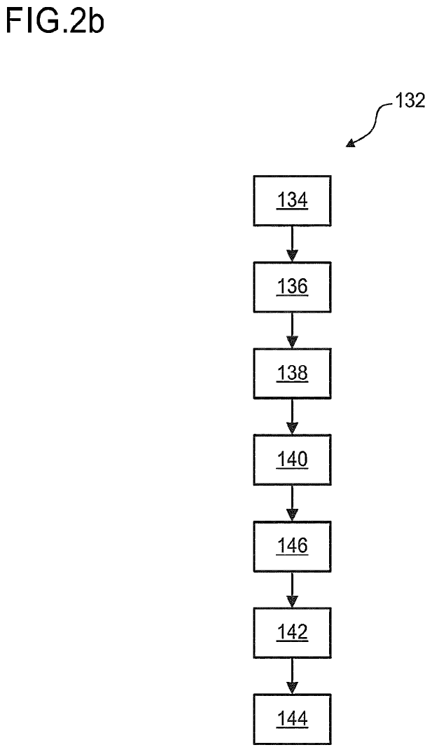

The spectrometer device 110 may be manufactured by a method of manufacturing at least one spectrometer device 110 for evaluating electromagnetic radiation, i.e. by a manufacturing method 132. Different embodiments of the manufacturing method 132 are illustrated in FIGS. 2a and 2b. The manufacturing method 132 comprises at least the following steps:
a) (denoted with reference number 134) providing at least one electro-optical system 114 configured for generating at least one electronic signal according to the electromagnetic radiation;
b) (denoted with reference number 136) providing at least one readout integrated circuit (ROIC) 116 for processing the at least one electronic signal;
c) (denoted with reference number 138) providing at least one circuit carrier 112;
d) (denoted with reference number 140) arranging the electro-optical system 114 on the ROIC 116;
e) (denoted with reference number 142) bonding the electro-optical system 114 and the ROIC 116 such as to establish at least one electrical connection between the electro-optical system 114 and the ROIC 116;
f) (denoted with reference number 144) arranging the ROIC 116 on the circuit carrier 112, such that the ROIC 116 is located between the electro-optical system 114 and the circuit carrier 112.

As an example, the manufacturing method 132 may further comprise step g) (denoted with reference number 146) of singulating the ROIC from a ROIC wafer 148. Thus, in step b), the ROIC 116 may be provided in form of the ROIC wafer 148. Alternatively however, in step b), the ROIC 116 may be provided as a singulated ROIC 150, i.e. as a previously singulated bare semiconductor chip.

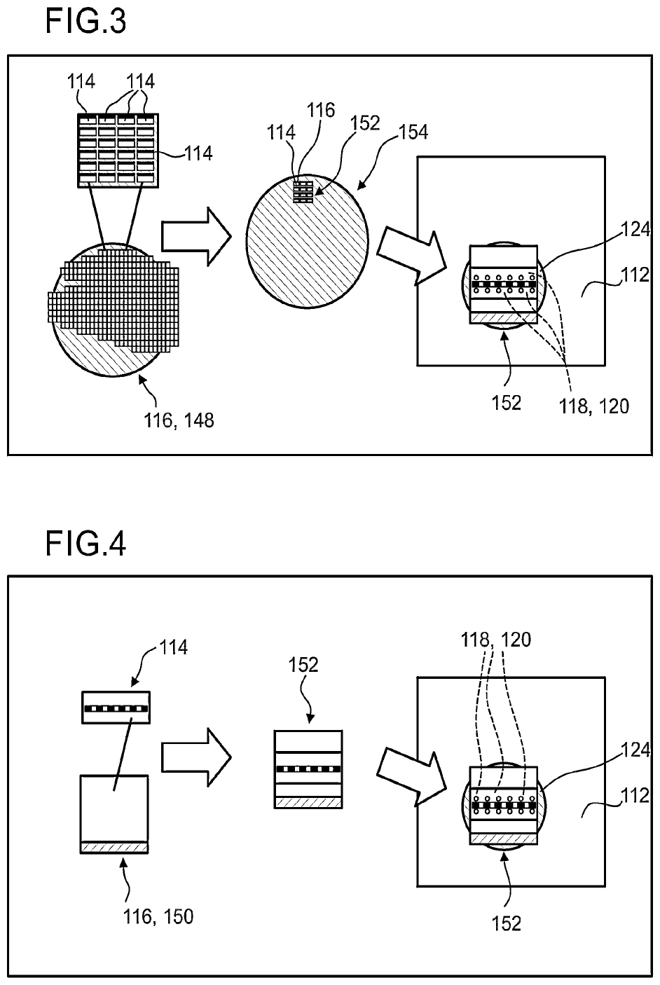

In FIG. 3, a schematic illustration of a manufacturing method 132 is shown. In particular, the ROIC 116 may be provided as a ROIC wafer 148, i.e. in step b), and the electro-optical system 114 may be arranged on, i.e. in step d), and bonded to, i.e. in step e), the ROIC 116 while the ROIC 116 is still part of the wafer 148, such as on waferlevel. Thereby, e.g. as an intermediate product, a stack of electro-optical system 114 and ROIC 116 being still part of the ROIC wafer 148 may be generated, for example a spectrometer on chip stack 152 on a wafer, i.e. an SoC-stack-wafer 154. Before arranging the ROIC 116 on the circuit carrier 112 such that the ROIC 116 is located between the electro-optical system 114 and the circuit carrier 112, i.e. before performing step f), the SoC-stack-wafer 154 may be singulated into separate SoC-stacks 152. Further, when arranging the SoC-stack 152 on the circuit carrier 112, an adhesive material 124 may be applied between the SoC-stack 152 and the circuit carrier 112, e.g. for mechanically stabilizing the SoC-stack 152 on the circuit carrier 112.

In FIG. 4, a different schematic illustration of a manufacturing method 132 is shown. In particular, the ROIC 116 may be provided as a singulated ROIC 150, i.e. in step b), and the electro-optical system 114 may be arranged on, i.e. in step d), and bonded to, i.e. in step e), the singulated ROIC 150. Thereby, e.g. as an intermediate product, an SoC-stack 152 may be generated and may then, i.e. in step f), be arranged on the circuit carrier 112, such that the ROIC 116 is located between the electro-optical system 114 and the circuit carrier 112. Further, when arranging the SoC-stack 152 on the circuit carrier 112, an adhesive material 124 may be applied between the SoC-stack 152 and the circuit carrier 112, e.g. for mechanically stabilizing the SoC-stack 152 on the circuit carrier 112.

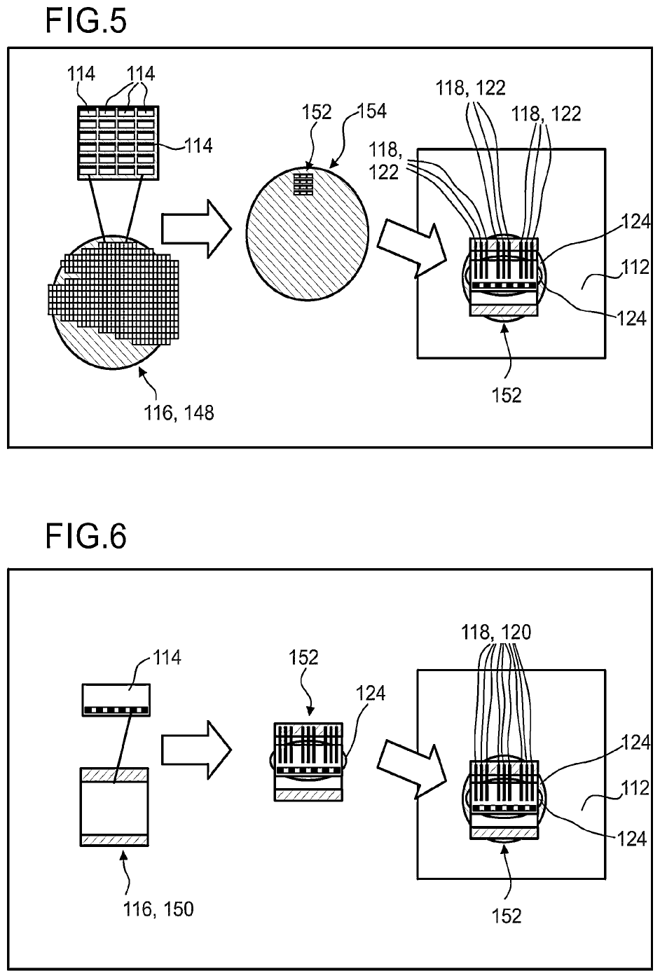

FIG. 5 shows a similar schematic illustration as shown in FIG. 3, and FIG. 6 shows a similar schematic illustration as shown in FIG. 4. However, instead of solder bumps 120 being used for bonding the electro-optical system 114 and the ROIC 116 such as to establish at least one electrical connection between the electro-optical system 114 and the ROIC 116, i.e. in the SoC-stack 152, multiple wires 122 may be used for establishing the electrical connection, while for mechanically stabilizing the arrangement of the SoC-stack, i.e. of the electro-optical system 114 on the ROIC 116, an adhesive material 124 may be used.

### LIST OF REFERENCE NUMBERS

110 spectrometer device
112 circuit carrier
114 electro-optical system
116 readout integrated circuit (ROIC)
118 interconnecting element
120 solder bump
122 wire
124 adhesive material
126 packaged chip
128 lead frame
130 housing
132 manufacturing method
134 step a)
136 step b)
138 step c)
140 step d)
142 step e)
144 step f)
146 step g)
148 ROIC wafer
150 singulated ROIC
152 spectrometer on chip stack (SoC-stack)
154 spectrometer on chip stack wafer (SoC-stack-wafer)

1. A method of manufacturing at least one spectrometer device for evaluating electromagnetic radiation, the method comprising:
a) providing at least one electro-optical system configured for generating at least one electronic signal according to the electromagnetic radiation;
b) providing at least one readout integrated circuit (ROIC) for processing the at least one electronic signal;
c) providing at least one circuit carrier;
d) arranging the electro-optical system on the ROIC, wherein step d) further comprises gluing the electro-optical system to the ROIC by applying at least one adhesive material, wherein the adhesive material is selected from the group consisting of: a thermosetting material; a thermoplastic material; a plastic material; a polymer material; and a silicone-based glue;
e) bonding the electro-optical system and the ROIC to establish at least one electrical connection between the electro-optical system and the ROIC; and
f) arranging the ROIC on the circuit carrier, such that the ROIC is located between the electro-optical system and the circuit carrier.

2. The method according to claim 1, wherein in step b) the at least one ROIC is provided as a ROIC wafer, wherein the method further comprises:
g) singulating the ROIC from the ROIC wafer.

3. The method according to claim 1, wherein step g) is performed after performing step d).

4. The method according to claim 1, wherein in step b) the at least one ROIC is provided as singulated ROIC.

5. The method according to claim 1, wherein in step e) the bonding comprises performing one or more of the processes selected from the group consisting of: a wire bonding process, a flip chip bonding process and a tape-automated boding process.

6. The method according to claim 1, wherein step f) comprises bonding the ROIC to the circuit carrier to establish at least one electrical connection between the ROIC and the circuit carrier.

7. The method according to claim 1, wherein step f) comprises packaging the ROIC with the electro-optical system thereby generating a packaged chip and then placing and bonding the packaged chip on the circuit carrier to establish at least one electrical connection between the packaged chip and the circuit carrier.

8. The method according to claim 1, wherein the method further comprises:
h) providing at least one housing and gluing the ROIC to the housing by applying at least one further adhesive material.

9. The method according to claim 1, wherein the further adhesive material is selected from the group consisting of: a thermosetting material, specifically an epoxy resin; a thermoplastic material; a plastic material; a polymer material; and a silicone-based glue.

10. A spectrometer device for evaluating electromagnetic radiation, the spectrometer device comprising:
at least one circuit carrier;
at least one electro-optical system configured for generating at least one electronic signal according to the electromagnetic radiation; and
at least one readout integrated circuit (ROIC) for processing the at least one electronic signal, wherein the ROIC is arranged between the circuit carrier and the electro-optical system, wherein the electro-optical system is glued to the ROIC by at least one adhesive material selected from the group consisting of: a thermosetting material; a thermoplastic material; a plastic material; a polymer material; and a silicone-based glue.

11. A spectrometer device, wherein the spectrometer device is manufactured at least partially by performing the method of manufacturing a spectrometer device according to claim 1.

12. The spectrometer device according to claim 10, wherein the electro-optical system comprises an array of individual pixel sensors, wherein each of the individual pixel sensors has at least one photosensitive area adapted for generating the at least one electronic signal depending on an illumination of the photosensitive area by at least a portion of the electromagnetic radiation.

13. The spectrometer device according to claim 10, wherein the ROIC comprises at least one bare semiconductor chip element previously separated from a wafer.

14. The spectrometer device according to claim 10, wherein the electro-optical system is bonded to the ROIC by at least one interconnecting element.

15. The spectrometer device according to claim 10, further comprising at least one wavelength-selective element configured for separating the electromagnetic radiation into a spectrum of constituent wavelength signals, wherein the wavelength-selective element is arranged in an optical path between a source of the electromagnetic radiation and the electro optical system.

16. The spectrometer device according to claim 10, further comprising at least one wavelength-selective element configured for separating the electromagnetic radiation into a spectrum of constituent wavelength signals, wherein the wavelength-selective element is arranged in an optical path between an external source of the electromagnetic radiation and the electro optical system.
